(19) United States
(12) Patent Application Publication
(10) Pub. No.: US 2011/0034032 A1
(43) Pub. Date: Feb. 10, 2011

(54) Method of formation or thermal spray coating

(75) Inventors: Toshiki Itoh, Nagoya-city (JP); Kouzou Yoshimura, Obu-city (JP); Ryonosuke Tera, Kariya-city (JP); Masashi Totokawa, Nagoya-city (JP); Yasunori Ninomiya, Kariya-city (JP)

Correspondence Address: HARNESS, DICKEY & PIERCE, P.L.C., P.O. BOX 828, BLOOMFIELD HILLS, MI, 48303, US

(73) Assignee: DENSO CORPORATION, Kariya-city (JP)

(21) Appl. No.: 12/802,497

(22) Filed: Jun. 8, 2010

(30) Foreign Application Priority Data
Jun. 10, 2009 (JP) 2009-139484
Apr. 7, 2010 (JP) 2010-088833

(51) Int. Cl. H01L 21/30

(52) U.S. Cl. 438/758; 257/E21.211

(57) ABSTRACT

A method of formation of a thermal spray coating which forms a thermal spray coating on a coating-forming surface, characterized by comprising a thermal spraying step of thermally spraying feedstock powder on the coating-forming surface and a deposition and coating forming step of having the thermally sprayed feedstock powder deposit on the coating-forming surface and solidify to form a coating, in the deposition and coating forming step, when deposited on the coating-forming surface by thermal spraying, the feedstock powder deposits in the solid phase state in 50 to 90%, preferably 70 to 80%, of the whole so as to raise the ratio of the crystallite remaining in the feedstock powder and secure a high heat conductivity.

### TECHNICAL FIELD

The present invention relates to a method of formation of a thermal spray coating securing a high heat conductivity.

### BACKGROUND ART

In the past, semiconductor devices radiating off heat from a semiconductor chip from its two surfaces have been proposed.

For example, Japanese Unexamined Patent Publication No. 2001-308237 discloses to enhance the cooling effect from the two surfaces of a semiconductor chip by bonding a pair of heat conducting members to the two surfaces of the semiconductor chip and covering them with a ceramic coating. This sort of ceramic coating is comprised of a thermal spray coating covering the external heat radiating surfaces of the heat conducting members. According to such a semiconductor card module, the pair of heat conducting members can be cooled through the ceramic coating, so it is considered possible to obtain a semiconductor device able to carry a much larger current compared with the past.

Japanese Unexamined Patent Publication No. 8-003718 discloses the following art for forming on the surface of a metal base material by thermally spraying a covering layer in which fine metal oxide particles are uniformly dispersed. This uses thermal spraying to cover the surface of an Ni-based, Co-based, or other heat resistant alloy base material with a powder of a corrosion resistant and oxidation resistant metal including metal oxide particles and comprised of coarse particles of a particle size of 100 μm or more and fine particles of 50 μm or less mixed together. In this case, as the metal oxides, Al₂O₃ or a rare earth metal oxide is used. 50 vol % or more of the total is made fine particles of a particle size of 1 μm or less. The ratio of the fine particles in the powder is made 0.2 to 1.0 by weight ratio with respect to the coarse particles. This invention covers a surface by thermal spraying, then performs heat treatment in a vacuum etc. at a 1200° C. or less temperature so as to further improve the corrosion resistance and oxidation resistance.

Japanese Unexamined Patent Publication No. 8-027558 discloses the following type of abrasion resistant thermal spray layer and a method for forming the same. That is, this comprises thermal spraying of a mixed powder of steel powder of a small particle size to be made to melt and steel powder of a large particle size to be made to disperse while not yet melted. Due to this, a high strength, thin walls, light weight, and other superior sliding properties can be obtained.

Furthermore, Japanese Unexamined Patent Publication No. 9-067662 discloses the art of forming a ceramic layer from a coarse particle aggregate layer arranged at the metal base material side and a fine particle aggregate layer arranged at the surface layer side of the ceramic layer. Due to this, heat resistance, electrical insulating ability, abrasion resistance, and corrosion resistance can be obtained.

However, none of the above-mentioned thermal spray coatings consider heat conductivity. In the dual-surface cooling type semiconductor card module shown in Japanese Unexamined Patent Publication No. 2001-308237, when it was necessary to increase the cooling effect from the two surfaces of the semiconductor chip, it was necessary to come up with a new thermal spraying method designed to raise the heat conductivity of the ceramic coating itself.

That is, in the method of formation of a thermal spray coating in Japanese Unexamined Patent Publication No. 2001-308237, at the coating-forming surface, the feedstock powder completely melts and the powder deposits in flat shapes. With rapid cooling, solidification and coating formation become possible in a state with the crystallite size made smaller by rapid cooling. For this reason, with this method, it is believed that, due to phonon scattering, the heat resistance is increased and therefore the heat conductivity is impaired.

### SUMMARY OF THE INVENTION

The present invention was made in consideration of the above problems. It reduces the ratio of a liquid phase part contributing to deposition of feedstock powder on the coating-forming surface and increases the ratio of a solid phase part so as to realize a thermal spray coating with a high heat conductivity. For example, it can also be applied to a dual-surface cooling type semiconductor card module.

To achieve the above object, the aspect of the invention as set forth in claim 1 comprises a method of formation of a thermal spray coating which forms a thermal spray coating (10) on a coating-forming surface, characterized by comprising a thermal spraying step of thermally spraying feedstock powder (P) on the coating-forming surface and a deposition and coating forming step of depositing the thermally sprayed feedstock powder (P) on the coating-forming surface and solidifying it to form a coating, in the deposition and coating forming step, when deposited on the coating-forming surface by thermal spraying, the feedstock powder (P) deposits in the solid phase state in 50 to 90%, preferably 70 to 80% of the whole so as to raise the ratio of the crystallite remaining in the feedstock powder (P) and secure a high heat conductivity.

Due to this, when depositing the feedstock powder (P) on the coating-forming surface by thermal spraying, 50 to 90% of the feedstock powder (P), preferably 70 to 80%, solidifies and is formed into a coating in the solid phase state, so it is possible to raise the ratio of crystallite remaining in the feedstock powder (P) and secure a high heat conductivity. That is, 50 to 90%, preferably 70 to 80%, of the feedstock powder (P) solidifying and being formed into a coating in the solid phase state means that, in the thermal spray coating as a whole, 50 to 90% of the feedstock powder (P), preferably 70 to 80%, solidifies and is formed into a coating in the state in which the original crystallite of the feedstock powder (P) remains. Further, leaving crystallite in the thermal spray coating leads to suppression of the photon scattering causing a drop in the heat conduction and to a high heat conductivity.

The aspect of the invention as set forth in claim 2 comprises the aspect of the invention as set forth in claim 1 characterized in that the feedstock powder (P) is comprised of big particle size powder (Pb) on the surface of which small particle size powder (Ps) is aggregated to form the feedstock powder (P).

Due to this, when thermally spraying the coating-forming surface, the big particle size powder (Pb) remains in a solid phase and the small particle size powder (Ps) can deposit on the surface of the big particle size powder (Pb) in the molten state to form a coating and therefore a thermal spray coating without the desired heat conductivity impaired can be obtained.

The aspect of the invention as set forth in claim 3 comprises the aspect of the invention as set forth in claim 1 characterized in that the feedstock powder (P) is classified into big particle size powder (Pb) and small particle size powder (Ps).

Due to this, when depositing the feedstock powder (P) on the coating-forming surface by thermal spraying for solidification, even if the small particle size powder (Ps) completely melts and forms a liquid phase state, the big particle size powder (Pb) remains in the solid phase state thereby enabling coating formation.

The aspect of the invention as set forth in claim 4 comprises the aspect of the invention as set forth in claim 3 characterized in that, in the deposition and coating forming step, before the small particle size powder (Ps) is deposited by thermal spraying on the coating-forming surface in the liquid phase state and the small particle size powder (Ps) solidifies, the big particle size powder (Pb) is deposited on the coating-forming surface in the solid phase state by controlling the thermal spraying timing in the thermal spraying step.

Due to this, the coating-forming surface is thermally sprayed by small particle size powder (Ps) in the completely molten state, then the big particle size powder (Pb) reaches the surface while still in the solid phase and is immobilized without detaching while forming a coating, so a thermal spray coating securing heat conductivity is obtained.

The aspect of the invention as set forth in claim 5 comprises the aspect of the invention as set forth in claim 3 characterized in that in the thermal spraying step, the big particle size powder (Pb) and the small particle size powder (Ps) are separately thermally sprayed and, in the deposition and coating forming step, at a position near the coating-forming surface, the big particle size powder (Pb) in the solid phase state and the small particle size powder (Ps) in the liquid phase state are made to collide with each other so that mixed solid phase and liquid phase state feedstock powder (P) is made to deposit on the coating-forming surface to form a coating.

Due to this, the big particle size powder (Pb) and the small particle size powder (Ps) are separately thermally sprayed toward the coating-forming surface where the thermal spray coating is to be formed in a manner so as to be mixed on the coating-forming surface. Due to this, by the still solid phase big particle size powder (Pb) and the liquid phase small particle size powder (Ps) colliding on the coating-forming surface, they deposit on the coating-forming surface in a mixed state enabling formation of a coating.

The aspect of the invention as set forth in claim 6 comprises the aspect of the invention as set forth in claim 3 characterized in that in the thermal spraying step, the plasma is controlled in accordance with the particle size of the feedstock powder (P) and, in the deposition and coating forming step, the coating-forming surface has the feedstock powder (P) with its inside in the solid phase state and with its surface side in the liquid phase state deposited on it for formation of a coating.

Due to this, the coating-forming surface is formed with a coating in a state including still solid phase big particle size powder (Pb) and together with liquid phase small particle size powder (Ps), so it is possible to obtain a thermal spray coating without detracting from the heat conductivity.

The aspect of the invention as set forth in claim 7 comprises the aspect of the invention as set forth in claim 6 characterized in that in the thermal spraying step, the plasma is controlled by adjusting a feed position of the feedstock powder (P) on a thermal spray path of a plasma gun (20G) in accordance with the particle size of the feedstock powder (P).

Due to this, since the feed position on the thermal spray path is controlled in accordance with the particle size, it becomes possible to deposit the powder in the solid phase state or deposit it in the liquid phase state in accordance with the particle size, so it is possible to obtain a thermal spray coating without detracting from the heat conductivity.

The aspect of the invention as set forth in claim 8 comprises a method of formation of a thermal spray coating which forms a thermal spray coating (10) on a coating-forming surface, characterized by comprising a step of coating big particle size powder (Pb) classified from feedstock powder (P) on the coating-forming surface as one layer and a thermal spraying step of thermally spraying small particle size powder (Ps) classified from the feedstock powder (P) on the coating-forming surface to fill in spaces between particles of the coated big particle size powder (Pb), the coating step and the thermal spraying step being repeatedly executed to obtain a coating of a desired thickness, and a ratio of presence of crystallite in the feedstock powder (P) being raised to secure a high heat conductivity.

Due to this, by repeating a coating step of first coating the coating-forming surface with the big particle size powder (Pb) in the solid phase state and a thermal spraying step of thermally spraying the small particle size powder (Ps) so as to fill in spaces between particles of the big particle size powder (Pb), it is possible to obtain a thermal spray coating of the desired thickness without detracting from the heat conductivity.

The aspect of the invention may comprise a method of formation of a thermal spray coating which forms a thermal spray coating (10) on a coating-forming surface, characterized by comprising a step of coating big particle size powder (Pb) classified from feedstock powder (P) on the coating-forming surface as one layer and a thermal spraying step of thermally spraying a plasma jet on the surface of the coated big particle size powder (Pb) to fill in spaces between particles of the coated big particle size powder (Pb), the coating step and the thermal spraying step being repeatedly executed to obtain a coating of a desired thickness, and a ratio of presence of crystallite in the feedstock powder (P) being raised to secure a high heat conductivity.

Due to this, by a thermal spraying step of thermally spraying the surface of the big particle size powder (Pb) coated by the coating step with a plasma jet to fill in the spaces between particles of the big particle size powder (Pb), the surface side of the big particle size powder (Pb) melts to form a liquid phase state. This liquid phase state big particle size powder (Pb) can be used to make the particles of the big particle size powder (Pb) solidify with the inside in the solid phase state. Therefore, by repeating the above coating step and thermal spraying step of filling in spaces by a plasma jet, it becomes possible to form a coating of the desired thickness securing heat conductivity.

The aspect of the invention as set forth in claim 9 comprises an aspect of the invention as set forth in claim 1 characterized in that coating-forming surface is formed with a coating while applying ultrasonic vibration so as to form a coating with few pores.

Due to this, formation of a coating with few pores and the desired thickness and securing heat conductivity becomes possible.

The aspect of the invention as set forth in claim 10 comprises the aspect of the invention as set forth in claim 1 characterized in that the feedstock powder (P) which is heat treated in advance to reform it to increase the crystallite size, is used.

Due to this, it is possible to form a coating while solidifying the powder with the crystallite size still large, so it is possible to contribute to securing the heat conductivity.

Further, the aspect of the invention as set forth in claim 11 comprises an aspect of the invention as set forth in claim 3 characterized in that the big particle size powder (Pb) has a particle size of 30 μm to 100 μm and the small particle size powder (Ps) has a particle size of 1 μm to 10 μm.

Due to this, by using small particle size powder (Ps) of a particle size of 1 μm to 10 μm and, on the other hand, big particle size powder (Pb) of a particle size of 30 μm to 100 μm, for example, it becomes possible to form a coating wherein even if using plasma for thermal spraying to cause the small particle size powder (Ps) to completely melt and form a liquid phase state, the big particle size powder (Pb) will not melt at the insides and will remain in the solid phase state. The aspect of the invention as set forth in claim 12 comprises the aspect of the invention as set forth in claim 3 characterized in that an average particle size of the big particle size powder (Pb) is 30 μm to 100 μm and an average particle size of the small particle size powder (Ps) is 1 μm to 10 μm.

The aspect of the invention as set forth in claim 13 comprises the aspect of the invention as set forth in claim 3 characterized in that, in the thermal spraying step, the big particle size powder (Pb) and the small particle size powder (Ps) are separately thermally sprayed and, in the deposition and coating forming step, at a position near the coating-forming surface, the big particle size powder (Pb), in mainly a solid phase state, and the small particle size powder (Ps), in mainly a liquid phase state, are made to collide with each other so as to make a mixed solid phase and liquid phase state feedstock powder (P) deposit on the coating-forming surface and form a coating.

The aspect of the invention as set forth in claim 14 comprises the aspect of the invention as set forth in claim 3 characterized in that, in the thermal spraying step, the feed positions of the big particle size powder (Pb) and the small particle size powder (Ps) of the feedstock powder are adjusted so that, in the deposition and coating forming step, at a position near the coating-forming surface, the big particle size powder (Pb), in mainly a solid phase state, and the small particle size powder (Ps), in mainly a liquid phase state, are made to collide with each other so as to make a mixed solid phase and liquid phase state feedstock powder (P) deposit on the coating-forming surface and form a coating.

The aspect of the invention as set forth in claim 15 comprises the aspect of the invention as set forth in claim 3 characterized in that, in the thermal spraying step, the feedstock powder (P) is separately thermally sprayed in accordance with the particle size of the powder and, in the deposition and coating forming step, the coating-forming surface has the feedstock powder (P) deposited on it with its inside in a solid phase state and its surface side in a liquid phase state so as to form a coating.

The aspect of the invention as set forth in claim 16 comprises the aspect of the invention as set forth in claim 3 characterized in that, in the thermal spraying step, the feed positions of the feedstock powder (P) are adjusted in accordance with the particle size of the powder so that, in the deposition and coating forming step, the coating-forming surface has the feedstock powder (P) deposited on it with its inside in a solid phase state and its surface side in a liquid phase state so as to form a coating.

The aspect of the invention as set forth in claim 17 comprises the aspect of the invention as set forth in claim 3 characterized in that as the big particle size powder, α alumina, magnesium oxide, silicon nitride, aluminum nitride, boronitride (c-BN), or a mixed powder of these is used.

These powders cannot be used much for a high heat conductivity thermal spray coating in ordinary thermal spraying, but are perfect for the big particle size powder. These materials can be used for that.

The aspect of the invention may comprise a method of formation of a thermal spray coating which forms a thermal spray coating (10) on a coating-forming surface, characterized by comprising a thermal spraying step of thermally spraying feedstock powder (P) on the coating-forming surface and a deposition and coating forming step of having the thermally sprayed feedstock powder (P) deposit on the coating-forming surface and solidify to form a coating, in which deposition and coating forming step, the powder is deposited so that the thermal spray coating deposited and solidified on the coating-forming surface has a crystallite size of 52 nm or more so as to raise the ratio of the crystallite remaining in the feedstock powder (P) and secure a high heat conductivity in forming the coating. Due to this, it is possible to obtain a thermal spray coating with a heat conductivity of 10W/m·K or more—one of the targets of a high conductivity insulating coating.

The aspect of the invention as set forth in claim 18 comprises a method of formation of a thermal spray coating which forms a thermal spray coating (10) on a coating-forming surface, characterized by comprising a thermal spraying step of thermally spraying feedstock powder (P) on the coating-forming surface and a deposition and coating forming step of having the thermally sprayed feedstock powder (P) deposit on the coating-forming surface and solidify it to form a coating, in the deposition and coating forming step, when depositing the feedstock powder (P) on the coating-forming surface by thermal spraying, it is deposited with 42% or more in a solid phase state so as to raise the ratio of the crystallite remaining in the feedstock powder (P) to secure a high heat conductivity in forming the coating.

The aspect of the invention as set forth in claim 19 comprises the aspect of the invention as set forth in claim 18 characterized in that in the deposition and coating forming step, when depositing the feedstock powder (P) on the coating-forming surface by thermal spraying, preferably it is deposited with 42 to 85% in a solid phase state so as to raise the ratio of the crystallite remaining in the feedstock powder (P) to secure a high heat conductivity in forming the coating.

The aspect of the invention as set forth in claim 20 comprises the aspect of the invention as set forth in any of the aspects of the invention as set forth in claims 1 to 19 characterized in that, in the deposition and coating forming step, the powder is cooled not from the coating-forming surface side, but from the back side of the substrate in forming the coating. Due to this, in cooling from the back surface, in addition to cooling by air, diverse cooling by water, a Peltier device, etc. becomes possible.

Note that the reference numerals in parentheses after the above means show the correspondence with specific means in the later explained embodiments.

The present invention may be more fully understood from the description of preferred embodiments of the invention, as set forth below, together with the accompanying drawings.

### BRIEF DESCRIPTION OF THE DRAWINGS

FIG. 1A is a view of an embodiment of a semiconductor card module using a thermal spray coating according to the present invention.

FIG. 1B is a cross-sectional explanatory view showing enlarged a thermal spray coating 10 shown in FIG. 1A.

FIG. 2 is a schematic cross-sectional explanatory view of a plasma gun and a coating-forming surface for explaining an embodiment of the method of formation of a thermal spray coating according to the present invention.

FIG. 3 is a schematic cross-sectional explanatory view of plasma guns and a coating-forming surface for explaining another embodiment of the method of formation of a thermal spray coating according to the present invention.

FIG. 4 is a schematic cross-sectional explanatory view of plasma guns and a coating-forming surface for explaining still another embodiment of the method of formation of a thermal spray coating according to the present invention.

FIG. 5 is a schematic view of feedstock powder comprised of big particle size powder to which small particle size powder is aggregated in the method of formation of a thermal spray coating according to the present invention.

FIG. 6 is a schematic cross-sectional explanatory view of a plasma gun and a coating-forming surface for explaining still another embodiment of the method of formation of a thermal spray coating according to the present invention.

FIG. 7 is a schematic explanatory view relating to the method of formation of a thermal spray coating using plasma thermal spraying shown for comparison with the method of formation of a thermal spray coating according to the present invention.

FIG. 8 is a view showing the relationship between crystallite size and heat conductivity.

FIG. 9 is a view showing the relationship between the solid phase ratio of the feedstock powder in the thermal spray coating and the crystallite size.

### DESCRIPTION OF EMBODIMENTS

Below, embodiments of a thermal spray coating formed using the method of formation of a thermal spray coating according to the present invention will be explained based on the attached drawings. Here, as an example of a semiconductor device, a semiconductor device comprised of a semiconductor chip from the two surfaces of which heat is radiated, wherein the semiconductor chip has a pair of heat conducting members bonded to its two principal planes and covered by a ceramic coating, will be explained.

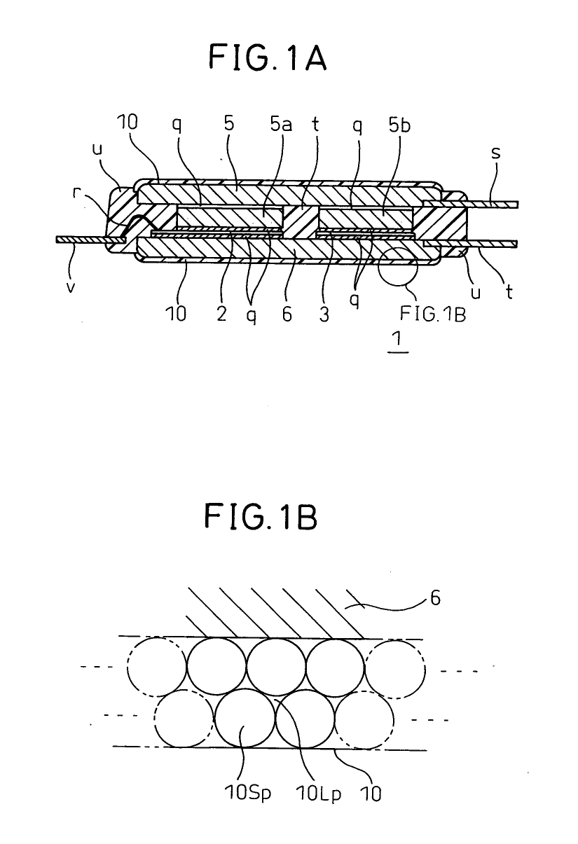

FIG. 1 A shows as an embodiment of a semiconductor a dual surface cooling type semiconductor card module 1 (below, referred to as a “semiconductor card module 1”).

In this semiconductor card module 1, the first and second heat conducting members 5, 6 bonded to the two principal planes of semiconductor chips 2, 3 are covered by a thermal spray coating 10 (below, “ceramic coating 10”).

The semiconductor chips 2, 3 are soldered on the inside principal plane of the second heat conducting member 6. On the principal plane of the other side of the semiconductor chip 2, a spacer 5a is soldered, while on the principal plane on the other side of the semiconductor chip 3, a spacer 5b is soldered. The spacers 5a and 5b respectively have thicknesses for absorbing the difference in thicknesses of the semiconductor chips 2, 3. Due to this, the principal planes of the spacers 5a, 5b at the opposite sides to the semiconductor chips 2, 3 are made the same heights and are soldered to the inside principal plane of the first heat conducting member 5.

q indicates a solder layer, r indicates a bonding wire, s, t indicate main electrode terminals, u indicates a sealing resin part, and v indicates a control electrode terminal.

The spacers 5a, 5b, first heat conducting member 5, and heat conducting metal plate 6 are comprised of metal sheets formed by copper, tungsten, molybdenum, etc.

The ceramic coating 10 covers the outside principal plane of the first heat conducting member 5 and the outside principal plane of the second heat conducting member 6. The ceramic coating 10 is formed by thermally spraying aluminum oxide (alumina) etc. on the outside principal plane of the first heat conducting member 5 and the outside principal plane of the second heat conducting member 6. The outside principal planes of the first heat conducting member 5 and second heat conducting member 6 are roughened before thermal spraying to improve the adhesion of the ceramic coating 10. The ceramic coating 10 further covers the corner parts forming the peripheral edges of the outside principal planes of the first heat conducting member 5 and the second heat conducting member 6 and parts of the side surfaces of the first heat conducting member 5 and second heat conducting member 6 connecting to these corner parts. The corner parts forming the peripheral edges of the outside principal planes of the first heat conducting member 5 and the second heat conducting member 6 are chamfered by at least a radius of curvature larger than the corner parts forming the peripheral edges of the inside principal planes so that the bonding with the ceramic coating 10 becomes stronger.

The ceramic coating 10 is formed by thermally spraying the coating-forming surface with feedstock powder P. The ceramic coating 10 has a solid phase part 10Sp comprised of big particle size (30 μm to 100 μm) powder Pb deposited on the coating-forming surface in a solid phase state and a liquid phase part 10Lp comprised of small particle size (1 μm to 10 μm) powder Ps deposited on the coating-forming surface in a liquid phase state and solidified together with the solid phase part 10Sp. As explained later, the ceramic coating 10 may also be formed using an even particle size distribution powder solidified with its surface side in the liquid phase state and its inside in the solid phase state.

Next, the steps for using the method of formation according to the present invention to form the ceramic coating 10 in the above semiconductor card module 1 will be explained.

This method of formation is performed using a generally used plasma thermal spraying apparatus 20.

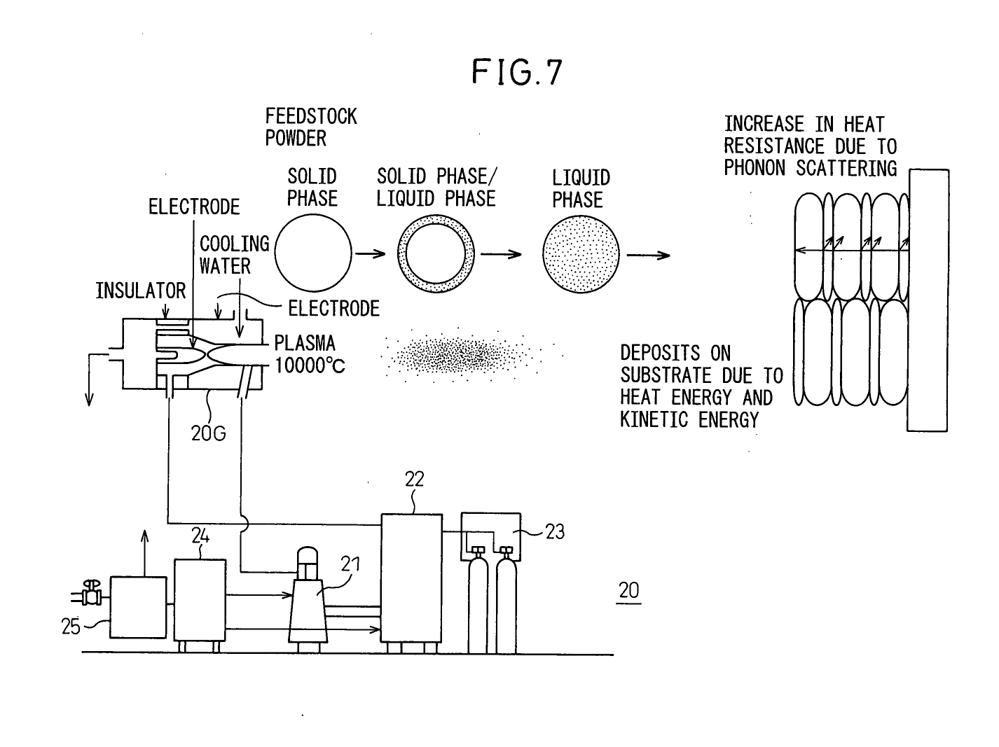

The plasma thermal spraying apparatus 20, for example, is comprised of a plasma gun 20G, powder feeder 21, control console 22, gas regulator 23, stable DC power supply 24, and cooler 25 (see FIG. 7).

Due to this configuration, for example, a DC arc discharge is caused between the anode and cathode in an argon, nitrogen, helium (inert gas), or other working gas so as to generate an over 10000° C. high temperature high speed plasma jet. Into this, a powder of a metal, cermet, ceramic, etc. is charged for melting and acceleration to form a coating at a thermally sprayed location.

This method of formation inherently comprises thermally spraying and depositing a feedstock powder P on the coating-forming surface of the first and second heat conducting members 5, 6 during which time raising the ratio of solidification in the solid phase state to form the coating and as a result stopping the drop in crystallite size of the feedstock powder P. By raising the ratio of maintenance of the crystallite size in the coating as a whole in forming the coating, phonon scattering, considered a cause of drop in heat conductivity, is suppressed and a higher heat conductivity is achieved. If forming a coating in this way, any technique can be employed.

Below, embodiments of the method of formation of the present invention will be explained.

### Method of Formation 1

1. Feedstock powder . . . alumina powder or spinel powder
2. Particle size . . . 30 μm to 100 μm (big particle size) and 1 μm to 10 μm (small particle size)
3. Crystallite size . . . 60 to 80 nm.

This method of formation uses alumina powder (or spinel powder etc.) as the feedstock powder P. The plasma thermal spraying apparatus 20 uses the control console 22 to control the stabilized DC power supply 24, cooler 25, gas regulator 23, and powder feeder 21, drive the plasma gun 20G, and generate a plasma jet by control instructions based on the following settings and routine.

### (1) Classification of Feedstock Powder P

The feedstock powder P is classified by a predetermined classifying means into big particle size powder Pb of a predetermined particle size and small particle size powder Ps of a particle size smaller than the particle size of the big particle size powder Pb. After classification, this is fed through the powder feeder 21 to the plasma guns 20G. Here, the big particle size powder Pb is defined as having a particle size of 30 μm to 100 μm, while the small particle size powder Ps is defined as having a particle size of 1 μm to 10 μm.

### (2) Alternate Thermal Spraying By A Plasma Gun 20G of Big Particle Size Powder Pb And Small Particle Size Powder Ps At Predetermined Timings

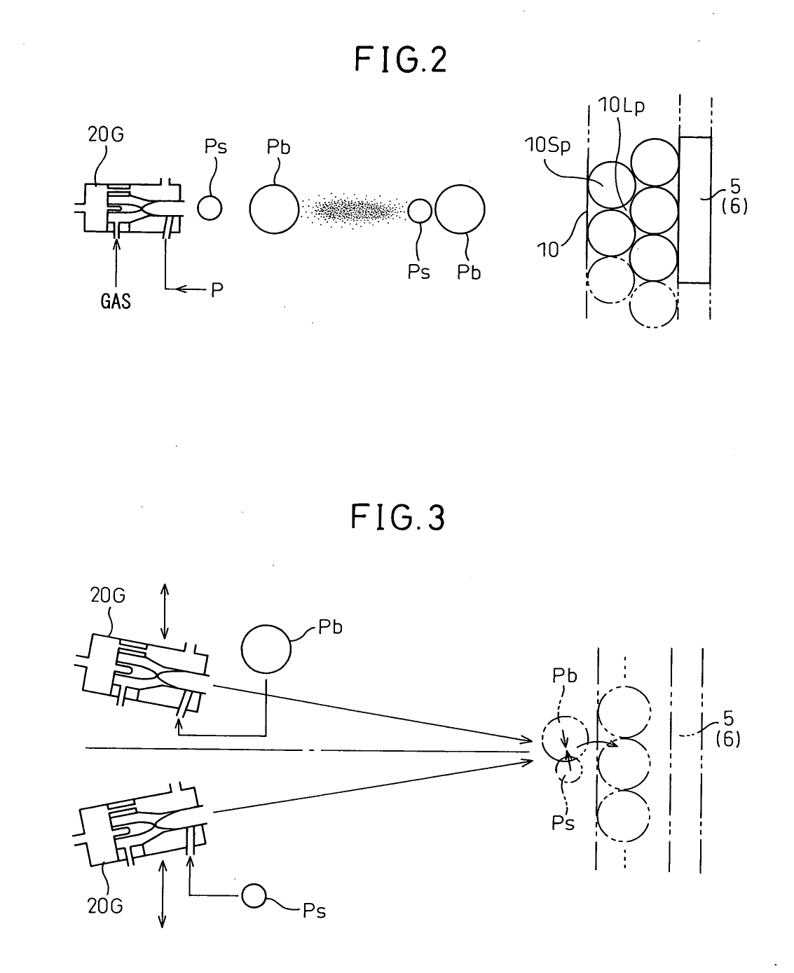

The plasma gun 20G generates a high temperature high speed plasma jet. Into this, through the powder feeder 21, the big particle size powder Pb and the small particle size powder Ps are charged at predetermined timings. These powders are melted and accelerated to be thermally sprayed on the coating-forming surface of the first and second heat conducting members 5, 6 at predetermined thermal spraying timings (see FIG. 2).

If feedstock powder P is charged into the plasma jet, depending on the particle size of the feedstock powder P, the powder gradually changes from a granular like solid phase to the solid phase/liquid phase and liquid phase due to the high temperature. The small particle size powder is completely melted by the heat energy and kinetic energy and deposits on the coating-forming surface in that state for the formation of the coating.

In the above mentioned process, the plasma gun 20G is controlled so that first the coating-forming surface of the first and second heat conducting members 5, 6 has the completely molten state small particle size powder Ps deposited on it, then has the big particle size powder Pb reach it in the solid phase. In this case, the big particle size powder Pb is thermally sprayed before the small particle size powder Ps solidifies. Due to this, at the first and second heat conducting members 5, 6, the big particle size powder Pb deposits while still in the solid phase and, further, between the particles of the big particle size powder Pb, the small particle size powder Ps is filled and solidified in the completely molten state for the formation of the coating. At this time, at the ceramic coating 10 formed, the solid phase state big particle size powder Pb is solidified using the liquid phase state (molten state) small particle size powder Ps as a binder in the state of the solid phase part 10Sp in about 50 to 90%, preferably 70 to 80%, and the liquid phase part 10Lp in about 10 to 50%, preferably 20 to 30% (see FIG. 1). In this way, the majority of the coating as a whole is occupied by the solid phase part 10Sp, so in the coating as a whole, an about 60 to 80 nm crystallite size can be maintained. As a result, as initially targeted, a thermal spray coating securing the desired heat conductivity is obtained.

The ratio of the solid phase state big particle size powder Pb and the liquid phase state (molten state) small particle size powder Ps differs depending on the differences in the feedstock powder. By using more suitable conditions, the best ratio for maintaining the crystallite size, a factor in the heat conductivity, can be derived.

### Method of Formation 2

This method of formation uses feedstock powder P classified into big particle size powder Pb and small particle size powder Ps and thermally sprays the big particle size powder Pb and the small particle size powder Ps by separate plasma guns 20G (two plasma guns 20G). The two plasma guns 20G, as shown in FIG. 3, are given tilt angles with respect to the coating-forming surface of the first and second heat conducting members 5, 6 and make the solid phase big particle size powder Pb and liquid phase small particle size powder Ps collide at a position near the coating-forming surface, that is, right above the first and second heat conducting members 5, 6, so as to be bonded there. Due to this, a solid phase/liquid phase powder is formed and deposited on the first and second heat conducting members 5, 6.

The plasma thermal spraying apparatus 20, in the same way as the above-mentioned method of formation, uses the control console 22 to control the stabilized DC power supply 24, cooler 25, gas regulator 23, and powder feeder 21, drive the plasma guns 20G, and generate plasma jets by control instructions based on the following settings and routine.

### (1) Classification of Feedstock Powder P

The feedstock powder P is classified by a predetermined classifying means into big particle size powder Pb and small particle size powder Ps. After classification, this is fed through the powder feeder 21 to the dedicated plasma guns 20G.

### (2) Driving Plasma Guns 20G Toward Coating-Forming Surface of First And Second Heat Conducting Members 5, 6

Due to this, the plasma guns 20G thermally spray plasma jets toward the first and second heat conducting members 5, 6 by predetermined tilt angles so as to strike the first and second heat conducting members 5, 6 while merging with each other. At this time, the plasma guns 20G are controlled so that the big particle size powder Pb reaches the first and second heat conducting members 5, 6 in the solid phase state and the small particle size powder Ps reaches them in the liquid phase state.

For this reason, right above the first and second heat conducting members 5, 6, at the close position where the powders merge, a solid phase/liquid phase powder of the solid phase big particle size powder Pb and the liquid phase small particle size powder Ps colliding and mixing together is formed and deposits on the first and second heat conducting members 5, 6. The plasma guns 20G are moved so that in this thermal spraying state, the coating-forming surface of the first and second heat conducting members 5, 6 as a whole is evenly struck. A coating is therefore formed on the first and second heat conducting members 5, 6 as a whole.

By the above steps, the first and second heat conducting members 5, 6 have the big particle size powder Pb deposited on them in the solid phase state and have the big particle size powder Pb surrounded by molten small particle size powder Ps. For this reason, due to the deposition of the solid phase state big particle size powder Pb, the crystallite size, a factor in the heat conductivity, is maintained at a high level. As a result, a thermal spray coating securing the desired heat conductivity is obtained.

### Method of Formation 3

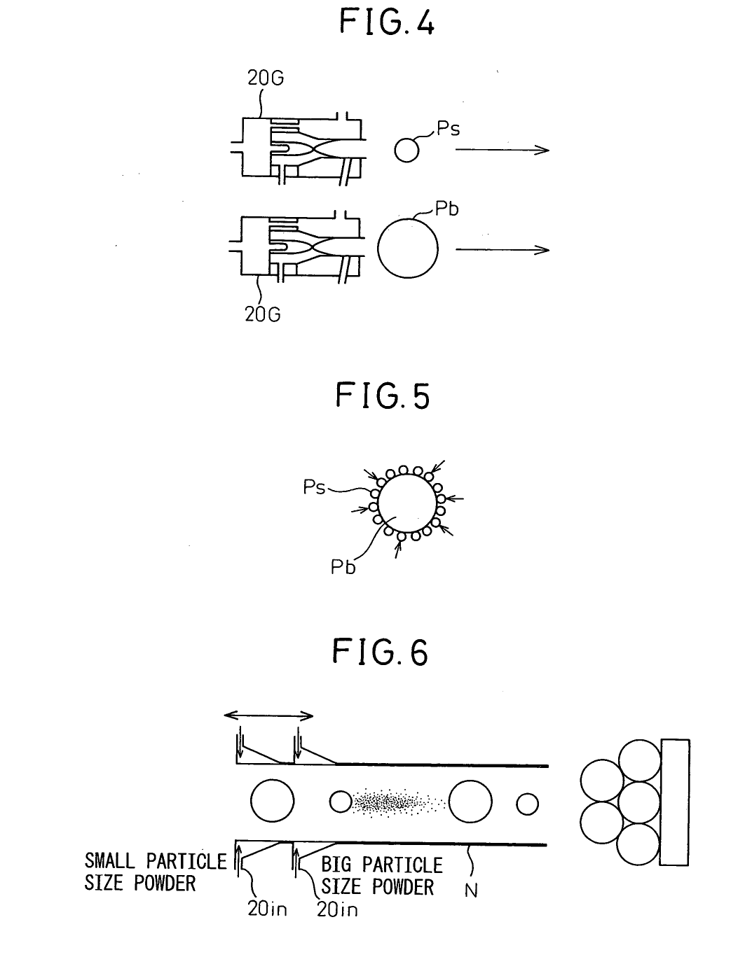

This method of formation classifies the feedstock and controls the plasma by a multiplasma head (plurality of plasma guns 20G) in accordance with the particle size to render the surface side of the feedstock powder P a molten state. For example, the small particle size powder Ps is thermally sprayed from the plasma gun 20G while keeping down the plasma power (that is, heat energy, kinetic energy). On the other hand, the big particle size powder Pb is thermally sprayed while raising the plasma power (see FIG. 4).

The plasma power can be adjusted by using the thermal console 22 in the plasma spraying apparatus 20 to control the feed rate of the working gas and the applied voltage.

### Method of Formation 4

This method of formation processes the feedstock powder P to obtain big particle size powder Pb on the surface of which small particle size powder Ps is aggregated and controls the plasma so that the surface side of the small particle size powder Ps melts (see FIG. 5).

In this case, for example, particle size 30 μm or so feedstock powder P is processed so that powder of one order or so smaller particle size is aggregated at its surface. This is fed through the powder feeder 21 to the plasma gun 20G. The control console 22 in the plasma thermal spraying apparatus 20 is used to control the feed rate of the working gas and the applied voltage to thereby adjust the power and melt the surface side of the small particle size powder Ps.

Due to this, the first and second heat conducting members 5 and 6 have the big particle size powder Pb deposited on them in the solid phase state. The big particle size powder Pb is surrounded by molten small particle size powder Ps for the formation of the coating.

### Method of Formation 5

This method of formation classifies the feedstock powder P and adjusts the feed positions to the plasma gun 20G on the thermal spray path by adjusting the positions of the inlets 20in for feeding feedstock powder to the plasma gun 20G in accordance with the particle size. This method of formation renders the surface side of the feedstock powder P a liquid phase (molten state) and renders the inside a solid phase and deposits the powder on the first and second heat conducting members 5, 6 so as to form the coating (see FIG. 6).

This plasma gun 20G is configured to be able to adjust the positions of the feedstock powder feed inlets 20in along the direction of ejection of the plasma jet.

For example, in the case of the big particle size powder Pb, the feedstock powder feed inlet 20in is adjusted in position to be near the downstream side of the ejection direction of the plasma jet at the nozzle part N of the plasma gun 20G so that the powder reaches the first and second heat conducting members 5, 6 while still in the solid phase. On the other hand, in the case of the small particle size powder Ps, the inlet is adjusted to be near the upstream side of the ejection direction of the plasma jet so that the powder reaches the first and second heat conducting members 5, 6 in the liquid phase state.

### Method of Formation 6

This method of formation is a method of formation repeating a thermal spraying step, comprising coating the big particle size powder Pb on the first and second heat conducting members 5, 6 in a single layer in the solid phase state, then thermally spraying the small particle size powder Ps to fill in the spaces between particles, until achieving a desired thickness. That is, the method is comprised of the following steps.
(1) Coating the big particle size powder in one layer.
(2) Thermally spraying the small particle size powder Ps to fill in the spaces between particles of the big particle size powder Pb.

At the step of (1), the big particle size powder Pb is coated by a predetermined means on the first and second heat conducting members 5, 6. At the step of (2), the plasma is controlled so that the small particle size powder Ps is rendered a liquid phase state until reaching the first and second heat conducting members 5, 6. By repeatedly executing such steps of (1) and (2), the first and second heat conducting members 5, 6 have the big particle size powder Pb deposited on them while still in the solid phase. Between the particles of the big particle size powder Pb, small particle size powder Ps is filled in a completely molten state and then solidified, so the ratio by which crystallite remains in the feedstock powder P can be increased in forming the coating.

### Method of Formation 7

This method of formation is a method of formation repeating a thermal spraying step, comprising coating a big particle size powder Pb in one layer, then using a plasma jet to fill in the spaces between particles, until achieving a desired thickness.

That is, in this method of formation, the two thermal spraying steps of (1) coating the big particle size powder Pb in one layer and (2) using a plasma jet for sintering to fill in the spaces between particles are repeated.

By such a method of formation as well, the first and second heat conducting members 5, 6 have the big particle size powder Pb deposited on them still in the solid phase. The spaces between particles of the particles of the big particle size powder Pb are filled by melting, then the powder is solidified, so the ratio of the crystallite remaining in the feedstock powder P can be raised in forming the coating.

### Method of Formation 8

This method of formation is a method forming the coating while applying ultrasonic vibration so as to form a coating with few pores. If using this method of formation in combination with the above method of formation 1 to method of formation 7, the thermal spray coatings formed by the method of formation 1 to the method of formation 7 can be formed with fewer pores. For the ultrasonic vibration generating means (not shown), a suitable existing one may be used to apply ultrasonic vibration on the first and second heat conducting members 5, 6 of the semiconductor card module 1 to be coated.

### Method of Formation 9

This method of formation employs the means of heat treating the feedstock powder P to increase the crystallite size. The feedstock powder P can for example be heat treated in a neutral or reducing atmosphere in a predetermined temperature range so as to increase the crystallite size.

After the feedstock powder P is reformed by the above mentioned heat treatment to be increased in crystallite size, it can be fed by the powder feeder 21 to the plasma gun 20G and thermally sprayed.

By using such reformed feedstock powder P to form a coating on the first and second heat conducting members 5, 6 in a still solid phase state, the object of the present invention can be achieved.

Here, for comparison, an example of a method of formation different from the method of formation of a thermal spray coating according to the present invention will be explained (see FIG. 7).

In this method of formation, a plasma thermal spraying apparatus 20 is used to deposit the feedstock powder P in a completely liquid phase state on the coating-forming surface.

That is, if feedstock powder P is charged into a plasma jet, the powder gradually shifts in phase from the granular solid state of the solid phase to the solid phase/liquid phase and the liquid phase due to the high temperature, is completely melted by the heat energy and kinetic energy, and in that state deposits on the coating-forming surface so as to form a coating on the coating-forming surface.

In this way, on the coating-forming surface, the feedstock powder P completely melts and deposits with the powder in a flattened state, so rapid cooling causes the crystallite size to become smaller than the crystallite size of the feedstock powder P in the original solid phase state and causes the powder to solidify in that state. It becomes difficult to secure a high heat conductivity.

Above, the method of formation of a thermal spray coating according to the present invention was explained illustrating a ceramic coating applied to a cooling type semiconductor card module and describing various methods of formation, but the following method of formation may also be considered.

A method of formation classifying the feedstock powder P using powder of different particle sizes with even, substantially uniform particle size distributions and controlling the plasma so as to make the surface side of the powder after classification a molten state so to form a coating on the coating-forming surface may also be considered. Due to this, the surface side solidifies in the liquid phase state, while the inner side solidifies in the solid phase state for the formation of the coating, so high heat conductivity can be secured.

Furthermore, the present invention is not limited to a cooling type semiconductor card module. Further, the feedstock powder P is also not limited to alumina powder (or spinel powder etc.) Depending on the product concerned, various powders, for example, metal oxide particles and alloy powders including Co, Cr, Al, Y, and Ni may be considered.

As the big particle size powder, α alumina, magnesium oxide, silicon nitride, aluminum nitride, boronitride (c-BN), or a mixed powder of these may be used. In ordinary thermal spraying, high heat conductivity α alumina ends up changing to low heat conductivity γ alumina, so this is unsuitable. Further, magnesium oxide is hygroscopic, so is unsuitable. The high heat conductivity silicon nitride, aluminum nitride, and boronitride end up oxidizing, so cannot be used as high heat conductivity thermal spray coatings. However, big particle size powder other than magnesium oxide is not melted much at all. This is perfect as big particle size powder. Further, even with magnesium oxide, this is covered by a low hygroscopic spinel material, so this material can be used as big particle size powder.

Next, another method of formation will be explained.

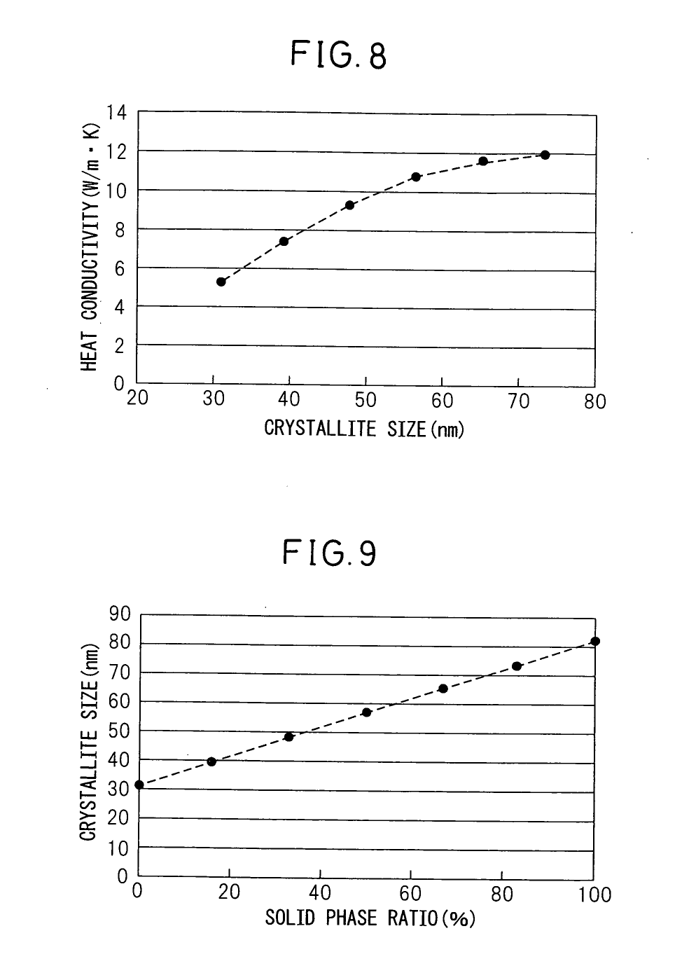

FIG. 8 is a view showing the relationship of the crystallite size and the heat resistance. FIG. 9 is a view showing the relationship of the solid phase ratio (ratio of feedstock powder reaching substrate in solid phase state) and the crystallite size.

As shown in FIG. 8, it was learned that when holding the porosity at the same extent (with the oil impregnation method, about 10%), the crystallite size increases and the heat conductivity of the spinel thermal spray coating increases. Therefore, it was discovered that to obtain a thermal spray coating having a heat conductivity of 10W/m·K or more—one target of the high conductivity insulating coating, the crystallite size has to be 52 nm or more.

As another method of formation, a method of formation of a thermal spray coating which forms a thermal spray coating 10 on a coating-forming surface comprising a thermal spraying step of thermally spraying feedstock powder P on the coating-forming surface and a deposition and coating forming step of having the thermally sprayed feedstock powder P deposit on the coating-forming surface and solidify to form a coating, wherein the thermal spray coating deposited and solidified on the coating-forming surface has a crystallite size of 52 nm or more. Furthermore, a high conductivity thermal spray coating formed by this method of formation of a thermal spray coating is also included in the present embodiments.

Further, in ordinary plasma thermal spraying, it was believed that almost all of the feedstock powder was melted in the plasma and rapidly solidified on the substrate, so the crystallite size fell to 30 nm+ (the crystallite size of the feedstock powder was 80 nm+). Based on this thinking, it is possible to increase the ratio of the feedstock powder reaching the substrate in the solid phase state so as to increase the average crystallite size in the thermal spray coating as a whole. As seen in FIG. 9, as a technique for increasing the crystallite size, increasing the ratio of the solid phase of the feedstock powder in the thermal spray coating is effective. However, if the ratio of the solid phase part increases, a tendency for the porosity of the thermal spray coating to increase appears. If the solid phase ratio exceeds 85%, control of the porosity becomes difficult and the efficiency of use of the feedstock powder remarkably falls.

From this, by using a method of formation of a thermal spray coating which forms a thermal spray coating 10 on a coating-forming surface comprising a thermal spraying step of thermally spraying feedstock powder P on the coating-forming surface and a deposition and coating forming step of having the thermally sprayed feedstock powder P deposit on the coating-forming surface and solidify to form a coating, in the deposition and coating forming step, when depositing the feedstock powder P on the coating-forming surface by thermal spraying, it is deposited with 42% or more in a solid phase state, so the ratio of the crystallite remaining in the feedstock powder (P) can be raised to secure a high heat conductivity. Further, in the deposition and coating forming step, when depositing the feedstock powder P on the coating-forming surface by thermal spraying, by depositing it with preferably 42 to 85% in a solid phase state, it is possible to raise the ratio of the crystallite remaining in the feedstock powder P to secure a high heat conductivity.

In cooling from the coating-forming surface side by air, when depositing the relatively inferior bonding strength solid phase state feedstock powder to the coating-forming surface, the ratio of the powder blown off by the air increases. To raise the solid phase ratio, therefore, a greater amount of solid phase feedstock becomes necessary, so the efficiency of use of the feedstock powder falls. To avoid this, in the deposition and coating forming step, the powder is cooled not from the coating-forming surface side, but from the back side of the substrate in forming the coating. Due to this, in cooling from the back, in addition to cooling by air, diverse cooling by water, a Peltier device, etc. becomes possible.

According to the present invention, when forming a thermal spray coating, the liquid phase part contributing to the deposition of the feedstock powder on the coating-forming surface is left reduced in ratio and the solid phase part is increased in ratio. Due to this, in the coating as a whole, the solid phase part enables the ratio of the crystallite, which relates to heat conductivity, remaining in the feedstock powder, to be raised, so it is possible to secure a high heat conductivity. For example, a thermal spray coating able to be applied to a dual surface cooling type semiconductor card module can be obtained.

While the invention has been described by reference to specific embodiments chosen for purposes of illustration, it should be apparent that numerous modifications could be made thereto by those skilled in the art without departing from the basic concept and scope of the invention.

1. A method of formation of a thermal spray coating which forms a thermal spray coating on a coating-forming surface, characterized by comprising
a thermal spraying step of thermally spraying feedstock powder on the coating-forming surface and
a deposition and coating forming step of depositing the thermally sprayed feedstock powder on said coating-forming surface and solidifying it to form a coating,
in said deposition and coating forming step, when deposited on the coating-forming surface by thermal spraying, said feedstock powder deposits in the solid phase state in 50 to 90%, preferably 70 to 80%, of the whole so as to raise the ratio of the crystallite remaining in the feedstock powder and secure a high heat conductivity.

2. A method of formation of a thermal spray coating as set forth in claim 1, characterized in that the feedstock powder is comprised of big particle size powder on the surface of which small particle size powder is aggregated to form the feedstock powder.

3. A method of formation of a thermal spray coating as set forth in claim 1 characterized in that the feedstock powder is classified into big particle size powder and small particle size powder.

4. A method of formation of a thermal spray coating as set forth in claim 3 characterized in that, in the deposition and coating forming step, before the small particle size powder is deposited by thermal spraying on the coating-forming surface in the liquid phase state and the small particle size powder solidifies, the big particle size powder is deposited on the coating-forming surface in the solid phase state by controlling the thermal spraying timing in the thermal spraying step.

5. A method of formation of a thermal spray coating as set forth in claim 3 characterized in that
in the thermal spraying step, the big particle size powder and the small particle size powder are separately thermally sprayed and,
in the deposition and coating forming step, at a position near the coating-forming surface, the big particle size powder in the solid phase state and the small particle size powder in the liquid phase state are made to collide with each other so that mixed solid phase and liquid phase state feedstock powder is made to deposit on said coating-forming surface to form a coating.

6. A method of formation of a thermal spray coating as set forth in claim 3 characterized in that in the thermal spraying step, the plasma is controlled in accordance with the particle size of the feedstock powder and, in the deposition and coating forming step, the coating-forming surface has the feedstock powder with its inside in the solid phase state and with its surface side in the liquid phase state deposited on it for formation of a coating.

7. A method of formation of a thermal spray coating as set forth in claim 6 characterized in that in the thermal spraying step, the plasma is controlled by adjusting a feed position of the feedstock powder on a thermal spray path of a plasma gun in accordance with the particle size of the feedstock powder.

8. A method of formation of a thermal spray coating which forms a thermal spray coating on a coating-forming surface, characterized by comprising
a step of coating big particle size powder classified from feedstock powder on the coating-forming surface as one layer and
a thermal spraying step of thermally spraying small particle size powder classified from said feedstock powder on the coating-forming surface to fill in spaces between particles of the coated big particle size powder,
the coating step and the thermal spraying step being repeatedly executed to obtain a coating of a desired thickness, and a ratio of presence of crystallite in the feedstock powder being raised to secure a high heat conductivity.

9. A method of formation of a thermal spray coating as set forth in claim 1 characterized in that coating-forming surface is formed with a coating while applying ultrasonic vibration so as to form a coating with few pores.

10. A method of formation of a thermal spray coating as set forth in claim 1 characterized in that the feedstock powder which is heat treated in advance to reform it to increase the crystallite size, is used.

11. A method of formation of a thermal spray coating as set forth in claim 3 characterized in that the big particle size powder (Pb) has a particle size of 30 μm to 100 μm and the small particle size powder has a particle size of 1 μm to 10 μm.

12. A method of formation of a thermal spray coating as set forth in claim 3 characterized in that an average particle size of the big particle size powder is 30 μm to 100 μm and an average particle size of the small particle size powder is 1 μm to 10 μm.

13. A method of formation of a thermal spray coating as set forth in claim 3 characterized in that, in said thermal spraying step, said big particle size powder and said small particle size powder are separately thermally sprayed and, in said deposition and coating forming step, at a position near said coating-forming surface, said big particle size powder, in mainly a solid phase state, and said small particle size powder, in mainly a liquid phase state, are made to collide with each other so as to make a mixed solid phase and liquid phase state feedstock powder deposit on said coating-forming surface and form a coating.

14. A method of formation of a thermal spray coating as set forth in claim 3 characterized in that, in said thermal spraying step, the feed positions of said big particle size powder and said small particle size powder of the feedstock powder are adjusted so that, in said deposition and coating forming step, at a position near said coating-forming surface, said big particle size powder, in mainly a solid phase state, and said small particle size powder, in mainly a liquid phase state, are made to collide with each other so as to make a mixed solid phase and liquid phase state feedstock powder deposit on said coating-forming surface and form a coating.

15. A method of formation of a thermal spray coating as set forth in claim 3 characterized in that, in said thermal spraying step, said feedstock powder is separately thermally sprayed in accordance with the particle size of the powder and, in said deposition and coating forming step, said coating-forming surface has said feedstock powder deposited on it with its inside in a solid phase state and its surface side in a liquid phase state so as to form a coating.

16. A method of formation of a thermal spray coating as set forth in claim 3 characterized in that, in said thermal spraying step, the feed positions of said feedstock powder are adjusted in accordance with the particle size of the powder so that, in said deposition and coating forming step, said coating-forming surface has said feedstock powder deposited on it with its inside in a solid phase state and its surface side in a liquid phase state so as to form a coating.

17. A method of formation of a thermal spray coating as set forth in claim 3 characterized in that as said big particle size powder, α alumina, magnesium oxide, silicon nitride, aluminum nitride, boronitride (c-BN), or a mixed powder of these is used.

18. A method of formation of a thermal spray coating which forms a thermal spray coating on a coating-forming surface, characterized by comprising
a thermal spraying step of thermally spraying feedstock powder on said coating-forming surface and a deposition and coating forming step of having the thermally sprayed feedstock powder deposit on said coating-forming surface and solidify to form a coating,
in said deposition and coating forming step, when depositing the feedstock powder on said coating-forming surface by thermal spraying, it is deposited with 42% or more in a solid phase state so as to raise the ratio of the crystallite remaining in the feedstock powder to secure a high heat conductivity in forming the coating.

19. A method of formation of a thermal spray coating as set forth in claim 18, characterized in that,
in said deposition and coating forming step, when depositing the feedstock powder on said coating-forming surface by thermal spraying, preferably it is deposited with 42 to 85% in a solid phase state so as to raise the ratio of the crystallite remaining in the feedstock powder to secure a high heat conductivity in forming the coating.

20. A method of formation of a thermal spray coating as set forth in claim 1 characterized in that, in said deposition and coating forming step, the powder is cooled not from said coating-forming surface side, but from the back side of the substrate in forming the coating.
